(19) United States
(12) Patent Application Publication
(10) Pub. No.: US 2024/0427606 A1
(43) Pub. Date: Dec. 26, 2024

(54) LOW TEMPERATURE BOOT STRATEGY FOR AUTONOMOUS VEHICLE COMPUTING SYSTEMS

(71) Applicants: Apollo Autonomous Driving USA LLC, Sunnyvale, CA (US); Beijing Baidu Netcom Science Technology Co., Ltd., Beijing (CN)

(72) Inventors: QIANG WANG, Sunnyvale, CA (US); ZHANBEI WANG, Beijing (CN); GUANGJUN LAN, Beijing (CN)

(21) Appl. No.: 18/026,649

(22) PCT Filed: Dec. 29, 2022
(86) PCT No.: PCT/CN2022/143544

§ 371 Date: Mar. 16, 2023

(51) Int. Cl. G06F 9/4401; G06F 11/14; G06F 11/30; H05K 7/20

(52) U.S. Cl. CPC G06F 9/4401; G06F 11/1417; G06F 11/3013; G06F 11/3058; H05K 7/20

(57) ABSTRACT

In one embodiment, a system monitors a temperature of a computing system for an autonomous driving system (ADS) of the autonomous driving vehicle (ADV). The system determines the monitored temperature is below a predetermined temperature threshold. The system controls a heating module to distribute heat to the computing system. The system determines the temperature of the computing system is above a predetermined temperature threshold. The system initiates a boot up sequence to boot up the computing system, where the temperature of components of the computing system is above the predetermined threshold when the boot up sequence is initiated.

### TECHNICAL FIELD

Embodiments of the present disclosure relate generally to operating autonomous driving vehicles. More particularly, embodiments of the disclosure relate to a low temperature boot strategy for autonomous driving vehicle (ADV) computing systems.

### BACKGROUND

Vehicles operating in an autonomous mode (e.g., driverless) can relieve occupants, especially the driver, from some driving-related responsibilities. When operating in an autonomous mode, the vehicle can navigate to various locations using onboard sensors, allowing the vehicle to travel with minimal human interaction or in some cases without any passengers.

Autonomous driving vehicles (ADVs) are intended to be widely adopted. ADVs are required to work under low temperature conditions in winter seasons. While stock automotive-grade components of an ADV can endure temperatures as low as −25 degree Celsius, the main computing systems for the autonomous driving system (ADS) typically uses server-grade components (e.g., CPU, GPU, memory, storage, switcher chip, etc.) which are not designed to withstand a low temperature environment.

### BRIEF DESCRIPTION OF THE DRAWINGS

Embodiments of the disclosure are illustrated by way of example and not limitation in the figures of the accompanying drawings in which like references indicate similar elements.

FIG. 1 is a block diagram illustrating a networked system according to one embodiment.

FIG. 2 is a block diagram illustrating an example of an autonomous driving vehicle according to one embodiment.

FIGS. 3A-3B are block diagrams illustrating an example of an autonomous driving system used with an autonomous driving vehicle according to one embodiment.

FIG. 4 is a block diagram illustrating an example of components for a safety system according to one embodiment.

FIG. 5 is a block diagram illustrating a process for a low temperature boot according to one embodiment.

FIG. 6 is a block diagram illustrating an example of a computing system for ADS according to one embodiment.

FIG. 7 is a block diagram illustrating a temperature curve according to one embodiment.

FIG. 8 is a flow diagram illustrating a process according to one embodiment.

### DETAILED DESCRIPTION

Various embodiments and aspects of the disclosure will be described with reference to details discussed below, and the accompanying drawings will illustrate the various embodiments. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

According to some embodiments, a low temperature boot strategy is employed for an autonomous driving vehicle (ADV) to function in low temperature conditions safely and reliably. Embodiments disclose an automotive-grade safety system that monitors the temperatures of a computing system for the autonomous driving system (ADS). When the monitored temperature is below a predetermined threshold, the safety system activates a heating module to heat the computing system. When the monitored temperature is above the predetermined threshold, the safety system initiates a boot sequence to boot up the computing system. The safety system can subsequently turn off the heating module.

Conventionally, the autonomous driving system (ADS) computing system uses server-grade components that are not designed to work at low temperatures. When an ADV powers on, via ignition, an operator typically monitors the temperature of an interior of the ADV, and waits before the operator boots up the computing system for the ADS. If the temperature has not reached a threshold, the boot up might fail and cause damages to various components of the ADS due to condensation and frost. For example, below the dew point, water condenses on electronic components which can cause corrosion or shorting. The dew point is the temperature which air cools to become saturated with water vapor. Factors such as temperature affects the dew point. When electronic components of the ADS are cooled below the dew point, water vapor can condense to form liquid water droplets on the electronic components which can damage the components when the ADS powers up in low temperature conditions.

According to a first aspect, a safety system monitors a temperature of a computing system for an autonomous driving system (ADS) of the autonomous driving vehicle (ADV). The system determines that the monitored temperature is below a predetermined temperature threshold. The system controls a heating module to distribute heat to the computing system. The system determines the temperature of the computing system is above a predetermined temperature threshold. The system initiates a boot up sequence to boot up the computing system, where the temperature of components of the computing system is above the predetermined threshold when the boot up sequence is initiated.

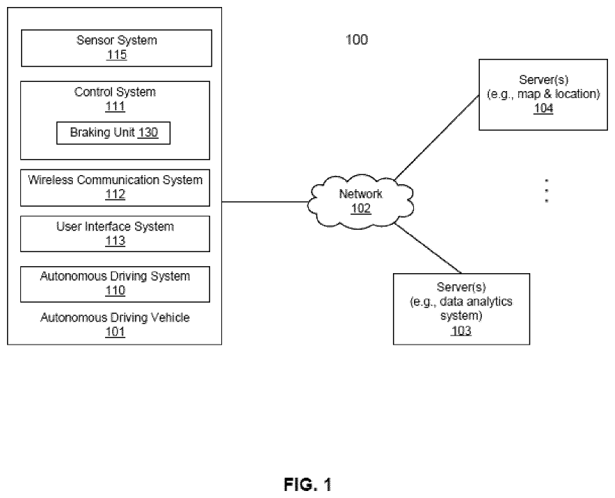

FIG. 1 is a block diagram illustrating an autonomous driving network configuration according to one embodiment of the disclosure. Referring to FIG. 1, network configuration 100 includes autonomous driving vehicle (ADV) 101 that may be communicatively coupled to one or more servers 103-104 over a network 102. Although there is one ADV shown, multiple ADVs can be coupled to each other and/or coupled to servers 103-104 over network 102. Network 102 may be any type of networks such as a local area network (LAN), a wide area network (WAN) such as the Internet, a cellular network, a satellite network, or a combination thereof, wired or wireless. Server(s) 103-104 may be any kind of servers or a cluster of servers, such as Web or cloud servers, application servers, backend servers, or a combination thereof. Servers 103-104 may be data analytics servers, content servers, traffic information servers, map and point of interest (MPOI) servers, or location servers, etc.

An ADV refers to a vehicle that can be configured to in an autonomous mode in which the vehicle navigates through an environment with little or no input from a driver. Such an ADV can include a sensor system having one or more sensors that are configured to detect information about the environment in which the vehicle operates. The vehicle and its associated controller(s) use the detected information to navigate through the environment. ADV 101 can operate in a manual mode, a full autonomous mode, or a partial autonomous mode.

In one embodiment, ADV 101 includes, but is not limited to, autonomous driving system (ADS) 110, vehicle control system 111, wireless communication system 112, user interface system 113, and sensor system 115. ADV 101 may further include certain common components included in ordinary vehicles, such as, an engine, wheels, steering wheel, transmission, etc., which may be controlled by vehicle control system 111 and/or ADS 110 using a variety of communication signals and/or commands, such as, for example, acceleration signals or commands, deceleration signals or commands, steering signals or commands, braking signals or commands, etc.

Components 110-115 may be communicatively coupled to each other via an interconnect, a bus, a network, or a combination thereof. For example, components 110-115 may be communicatively coupled to each other via a controller area network (CAN) bus. A CAN bus is a vehicle bus standard designed to allow microcontrollers and devices to communicate with each other in applications without a host computer. It is a message-based protocol, designed originally for multiplex electrical wiring within automobiles, but is also used in many other contexts.

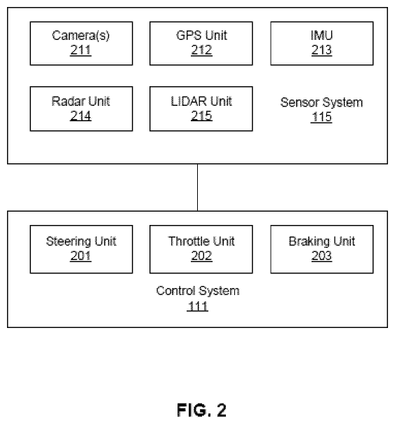

Referring now to FIG. 2, in one embodiment, sensor system 115 includes, but it is not limited to, one or more cameras 211, global positioning system (GPS) unit 212, inertial measurement unit (IMU) 213, radar unit 214, and a light detection and range (LIDAR) unit 215. GPS system 212 may include a transceiver operable to provide information regarding the position of the ADV. IMU unit 213 may sense position and orientation changes of the ADV based on inertial acceleration. Radar unit 214 may represent a system that utilizes radio signals to sense objects within the local environment of the ADV. In some embodiments, in addition to sensing objects, radar unit 214 may additionally sense the speed and/or heading of the objects. LIDAR unit 215 may sense objects in the environment in which the ADV is located using lasers. LIDAR unit 215 could include one or more laser sources, a laser scanner, and one or more detectors, among other system components. Cameras 211 may include one or more devices to capture images of the environment surrounding the ADV. Cameras 211 may be still cameras and/or video cameras. A camera may be mechanically movable, for example, by mounting the camera on a rotating and/or tilting a platform.

Sensor system 115 may further include other sensors, such as, a sonar sensor, an infrared sensor, a steering sensor, a throttle sensor, a braking sensor, and an audio sensor (e.g., microphone). An audio sensor may be configured to capture sound from the environment surrounding the ADV. A steering sensor may be configured to sense the steering angle of a steering wheel, wheels of the vehicle, or a combination thereof. A throttle sensor and a braking sensor sense the throttle position and braking position of the vehicle, respectively. In some situations, a throttle sensor and a braking sensor may be integrated as an integrated throttle/braking sensor.

In one embodiment, vehicle control system 111 includes, but is not limited to, steering unit 201, throttle unit 202 (also referred to as an acceleration unit), and braking unit 203. Steering unit 201 is to adjust the direction or heading of the vehicle. Throttle unit 202 is to control the speed of the motor or engine that in turn controls the speed and acceleration of the vehicle. Braking unit 203 is to decelerate the vehicle by providing friction to slow the wheels or tires of the vehicle. Note that the components as shown in FIG. 2 may be implemented in hardware, software, or a combination thereof.

Referring back to FIG. 1, wireless communication system 112 is to allow communication between ADV 101 and external systems, such as devices, sensors, other vehicles, etc. For example, wireless communication system 112 can wirelessly communicate with one or more devices directly or via a communication network, such as servers 103-104 over network 102. Wireless communication system 112 can use any cellular communication network or a wireless local area network (WLAN), e.g., using WiFi to communicate with another component or system. Wireless communication system 112 could communicate directly with a device (e.g., a mobile device of a passenger, a display device, a speaker within vehicle 101), for example, using an infrared link, Bluetooth, etc. User interface system 113 may be part of peripheral devices implemented within vehicle 101 including, for example, a keyboard, a touch screen display device, a microphone, and a speaker, etc.

Some or all of the functions of ADV 101 may be controlled or managed by ADS 110, especially when operating in an autonomous driving mode. ADS 110 includes the necessary hardware (e.g., processor(s), memory, storage) and software (e.g., operating system, planning and routing programs) to receive information from sensor system 115, control system 111, wireless communication system 112, and/or user interface system 113, process the received information, plan a route or path from a starting point to a destination point, and then drive vehicle 101 based on the planning and control information. Alternatively, ADS 110 may be integrated with vehicle control system 111.

For example, a user as a passenger may specify a starting location and a destination of a trip, for example, via a user interface. ADS 110 obtains the trip related data. For example, ADS 110 may obtain location and route data from an MPOI server, which may be a part of servers 103-104. The location server provides location services and the MPOI server provides map services and the POIs of certain locations. Alternatively, such location and MPOI information may be cached locally in a persistent storage device of ADS 110.

While ADV 101 is moving along the route, ADS 110 may also obtain real-time traffic information from a traffic information system or server (TIS). Note that servers 103-104 may be operated by a third party entity. Alternatively, the functionalities of servers 103-104 may be integrated with ADS 110. Based on the real-time traffic information, MPOI information, and location information, as well as real-time local environment data detected or sensed by sensor system 115 (e.g., obstacles, objects, nearby vehicles), ADS 110 can plan an optimal route and drive vehicle 101, for example, via control system 111, according to the planned route to reach the specified destination safely and efficiently.

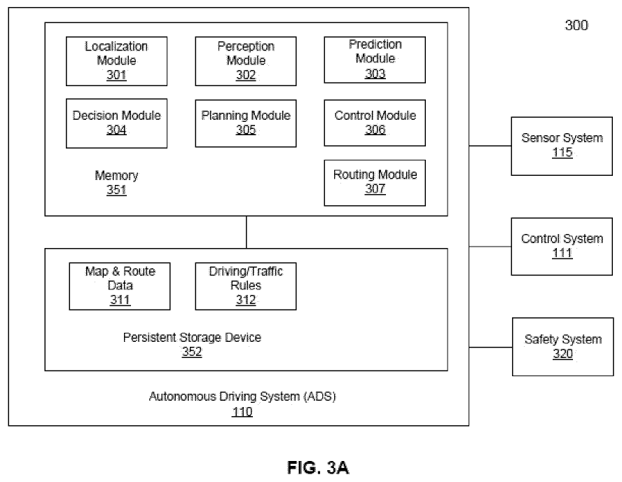

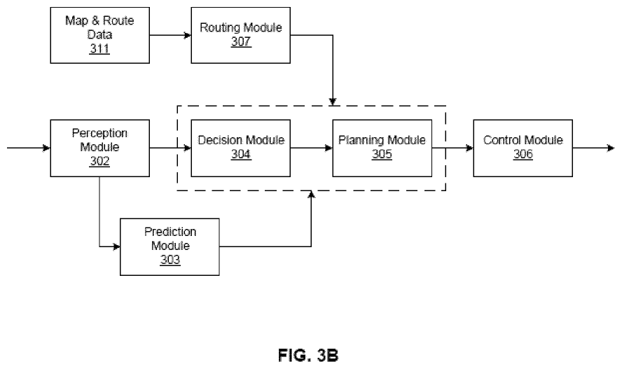

FIGS. 3A and 3B are block diagrams illustrating an example of an autonomous driving system used with an ADV according to one embodiment. System 300 may be implemented as a part of ADV 101 of FIG. 1 including, but is not limited to, ADS 110, control system 111, and sensor system 115. Referring to FIGS. 3A-3B, ADS 110 includes, but is not limited to, localization module 301, perception module 302, prediction module 303, decision module 304, planning module 305, control module 306, and routing module 307.

Some or all of modules 301-307 may be implemented in software, hardware, or a combination thereof. For example, these modules may be installed in persistent storage device 352, loaded into memory 351, and executed by one or more processors (not shown). Note that some or all of these modules may be communicatively coupled to or integrated with some or all modules of vehicle control system 111 of FIG. 2. Some of modules 301-307 may be integrated together as an integrated module.

Localization module 301 determines a current location of ADV 101 (e.g., leveraging GPS unit 212) and manages any data related to a trip or route of a user. Localization module 301 (also referred to as a map and route module) manages any data related to a trip or route of a user. A user may log in and specify a starting location and a destination of a trip, for example, via a user interface. Localization module 301 communicates with other components of ADV 101, such as map and route data 311, to obtain the trip related data. For example, localization module 301 may obtain location and route data from a location server and a map and POI (MPOI) server. A location server provides location services and an MPOI server provides map services and the POIs of certain locations, which may be cached as part of map and route data 311. While ADV 101 is moving along the route, localization module 301 may also obtain real-time traffic information from a traffic information system or server.

Based on the sensor data provided by sensor system 115 and localization information obtained by localization module 301, a perception of the surrounding environment is determined by perception module 302. The perception information may represent what an ordinary driver would perceive surrounding a vehicle in which the driver is driving. The perception can include the lane configuration, traffic light signals, a relative position of another vehicle, a pedestrian, a building, crosswalk, or other traffic related signs (e.g., stop signs, yield signs), etc., for example, in a form of an object. The lane configuration includes information describing a lane or lanes, such as, for example, a shape of the lane (e.g., straight or curvature), a width of the lane, how many lanes in a road, one-way or two-way lane, merging or splitting lanes, exiting lane, etc.

Perception module 302 may include a computer vision system or functionalities of a computer vision system to process and analyze images captured by one or more cameras in order to identify objects and/or features in the environment of the ADV. The objects can include traffic signals, road way boundaries, other vehicles, pedestrians, and/or obstacles, etc. The computer vision system may use an object recognition algorithm, video tracking, and other computer vision techniques. In some embodiments, the computer vision system can map an environment, track objects, and estimate the speed of objects, etc. Perception module 302 can also detect objects based on other sensors data provided by other sensors such as a radar and/or LIDAR.

For each of the objects, prediction module 303 predicts what the object will behave under the circumstances. The prediction is performed based on the perception data perceiving the driving environment at the point in time in view of a set of map/route information 311 and traffic rules 312. For example, if the object is a vehicle at an opposing direction and the current driving environment includes an intersection, prediction module 303 will predict whether the vehicle will likely move straight forward or make a turn. If the perception data indicates that the intersection has no traffic light, prediction module 303 may predict that the vehicle may have to fully stop prior to enter the intersection. If the perception data indicates that the vehicle is currently at a left-turn only lane or a right-turn only lane, prediction module 303 may predict that the vehicle will more likely make a left turn or right turn respectively.

For each of the objects, decision module 304 makes a decision regarding how to handle the object. For example, for a particular object (e.g., another vehicle in a crossing route) as well as its metadata describing the object (e.g., a speed, direction, turning angle), decision module 304 decides how to encounter the object (e.g., overtake, yield, stop, pass). Decision module 304 may make such decisions according to a set of rules such as traffic rules or driving rules 312, which may be stored in persistent storage device 352.

Routing module 307 is configured to provide one or more routes or paths from a starting point to a destination point. For a given trip from a start location to a destination location, for example, received from a user, routing module 307 obtains route and map information 311 and determines all possible routes or paths from the starting location to reach the destination location. Routing module 307 may generate a reference line in a form of a topographic map for each of the routes it determines from the starting location to reach the destination location. A reference line refers to an ideal route or path without any interference from others such as other vehicles, obstacles, or traffic condition. That is, if there is no other vehicle, pedestrians, or obstacles on the road, an ADV should exactly or closely follows the reference line. The topographic maps are then provided to decision module 304 and/or planning module 305. Decision module 304 and/or planning module 305 examine all of the possible routes to select and modify one of the most optimal routes in view of other data provided by other modules such as traffic conditions from localization module 301, driving environment perceived by perception module 302, and traffic condition predicted by prediction module 303. The actual path or route for controlling the ADV may be close to or different from the reference line provided by routing module 307 dependent upon the specific driving environment at the point in time.

Based on a decision for each of the objects perceived, planning module 305 plans a path or route for the ADV, as well as driving parameters (e.g., distance, speed, and/or turning angle), using a reference line provided by routing module 307 as a basis. That is, for a given object, decision module 304 decides what to do with the object, while planning module 305 determines how to do it. For example, for a given object, decision module 304 may decide to pass the object, while planning module 305 may determine whether to pass on the left side or right side of the object. Planning and control data is generated by planning module 305 including information describing how vehicle 101 would move in a next moving cycle (e.g., next route/path segment). For example, the planning and control data may instruct vehicle 101 to move 10 meters at a speed of 30 miles per hour (mph), then change to a right lane at the speed of 25 mph.

Based on the planning and control data, control module 306 controls and drives the ADV, by sending proper commands or signals to vehicle control system 111, according to a route or path defined by the planning and control data. The planning and control data include sufficient information to drive the vehicle from a first point to a second point of a route or path using appropriate vehicle settings or driving parameters (e.g., throttle, braking, steering commands) at different points in time along the path or route.

In one embodiment, the planning phase is performed in a number of planning cycles, also referred to as driving cycles, such as, for example, in every time interval of 100 milliseconds (ms). For each of the planning cycles or driving cycles, one or more control commands will be issued based on the planning and control data. That is, for every 100 ms, planning module 305 plans a next route segment or path segment, for example, including a target position and the time required for the ADV to reach the target position. Alternatively, planning module 305 may further specify the specific speed, direction, and/or steering angle, etc. In one embodiment, planning module 305 plans a route segment or path segment for the next predetermined period of time such as 5 seconds. For each planning cycle, planning module 305 plans a target position for the current cycle (e.g., next 5 seconds) based on a target position planned in a previous cycle. Control module 306 then generates one or more control commands (e.g., throttle, brake, steering control commands) based on the planning and control data of the current cycle.

Note that decision module 304 and planning module 305 may be integrated as an integrated module. Decision module 304/planning module 305 may include a navigation system or functionalities of a navigation system to determine a driving path for the ADV. For example, the navigation system may determine a series of speeds and directional headings to affect movement of the ADV along a path that substantially avoids perceived obstacles while generally advancing the ADV along a roadway-based path leading to an ultimate destination. The destination may be set according to user inputs via user interface system 113. The navigation system may update the driving path dynamically while the ADV is in operation. The navigation system can incorporate data from a GPS system and one or more maps so as to determine the driving path for the ADV.

Referring to FIG. 3A, in one embodiment, system 300 can be implemented to include safety system 320. Safety system 320 can include a Microcontroller Unit (MCU), field programmable gate array (FPGA), complex programmable logic device (CPLD), or system-on-a-chip (SOC)-based controller that is used for system control and health monitoring of ADS 110. The hardware components of safety system can be automotive-grade electronic components that function reliably at low temperature settings. Automotive-grade electronics are specially-designed electronics intended for use in automobiles. Automotive electronics can be subjected to, and are therefore rated at, more extreme temperature ranges than commercial (i.e., server-grade) electronics. An example temperature range for automotive-grade electronics can be: −40° C. to 125° C. Whereas, consumer electronics, such as server-grade electronics, are graded to function for a temperature range of: 0° C. to 85° C.

From a hardware design perspective, the safety system can be physically separated from the autonomous driving system (ADS) computing system 110. In one embodiment, the safety system is boot up first, after the safety system performs safety-related checking, such as temperature, voltage, and components health status checks, etc., for ADS 110, safety system then initiates the boot sequence for the main ADS computing system. For the ADV to function reliably under low temperature conditions, the safety system can first assess the temperature of computing system and control a thermal management system of ADV to heat up the computing system when the temperature is below a threshold, e.g., 0 degrees Celsius. When the temperature reaches a safe region, e.g., above 0 degrees Celsius, the safety system then initiates the boot sequence to turn on the main ADS computing system.

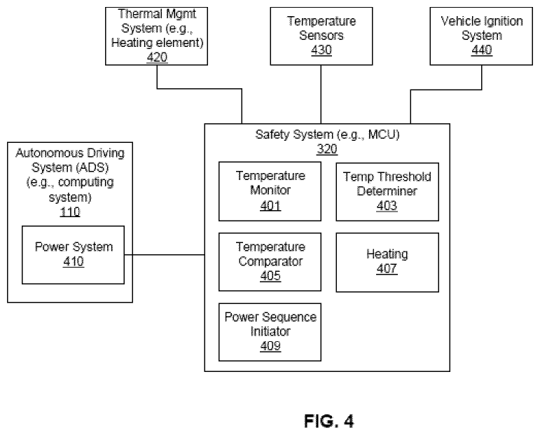

FIG. 4 is a block diagram illustrating an example of components for a safety system 320 according to one embodiment. In one embodiment, safety system 320 is communicatively coupled to power system 410 of ADS computing system 110, thermal management system 420, temperature sensors 430, and vehicle ignition system 440. In one embodiment, power system 410 can be implemented as a programmable power management chip (PMIC), a programmable logic chip such as: a field programmable gate array (FPGA), or a complex programmable logic device (CPLD), or the like. Safety system can be implemented as a MCU, FPGA, or system-on-a-chip (SoC), or the like.

Safety system 320 can include modules, such as, temperature monitor 401, temperature threshold determiner 403, temperature comparator 405, heat activator 407, and power sequence initiator 409. In one embodiment, safety system 320 can power up in response to a power signal from ignitions system 440. The ignition system 440 can represent the power up of the ADV, e.g., ignition for a combustion engine vehicle or a battery voltage for an electric vehicle. When powered up, safety system 320 can receive sensor data from temperature sensors 430 to monitor, via temperature monitor 401, temperatures of different components of ADS 110. Safety system 320 can determine the desired temperature thresholds, via temperature threshold determiner 403, for different temperature-sensitive components (e.g., CPU, GPU, digital signal processors (DSP), battery, memory devices, storage devices, SoC, temperature sensitive switch chips, etc.) of ADS 110. Safety system 320 can compare the monitored temperatures with the desired temperatures, via temperature comparator 405. When the monitored temperature is below the desired thresholds, safety system 320 can activate heating element 420, via heat activator 407, to heat the components of ADS 110. When the monitored temperature is above the desired thresholds, safety system 320 can signal power system 410 to boot up ADS 110, via power sequence initiator 409. Some of modules 401-409 can be integrated into a single integrated module.

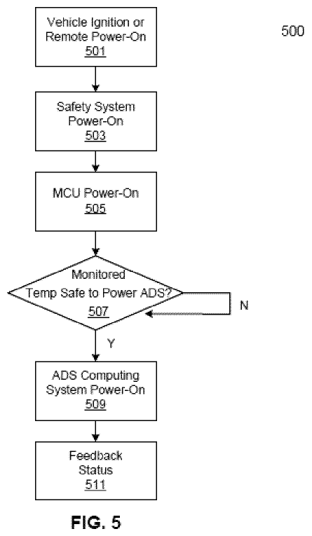

FIG. 5 is a block diagram illustrating a process 500 for a low temperature boot according to one embodiment. Process 500 may be performed by processing logic which may include software, hardware, or a combination thereof. For example, process 500 may be performed by electronic components of ADV 101, such as vehicle ignition system 440, temperature sensor 430, thermal management system 420, ADS 110, and/or safety system 320 of FIG. 4.

At block 501, ADV 101 receives a vehicle ignition or remote power on signal from a key fob (a small handheld remote control device that controls a remote keyless entry for ADV 101).

At block 503, vehicle ignition provides a power to safety system to power on safety system. Power can be provided as a direct current (DC) voltage from a battery of ADV 101.

At block 505, if the safety system is MCU-based, the power signal powers up the MCU. If the safety system is FPGA or CPLD-based, power signal powers up the FPGA or CPLD.

At block 507, MCU monitors the temperature of the computing system ADS 110 using temperature sensors distributed on a server board of computing system ADS 110. MCU then determines if it is safe to power on the ADS.

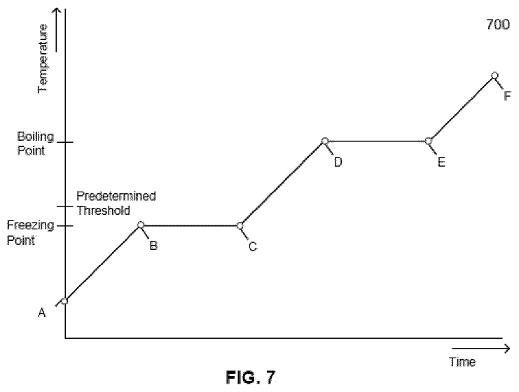

The ADS is safe to power on when temperature-critical components of ADS 110 are within their respective operating temperature ranges. In an embodiment, a predetermined temperature threshold is determined from each of the temperature-critical components of ADS 110. For example, the predetermined temperature threshold can be determined as the lower bound of the temperature ranges for a component. For example, for components with operating ranges: 0 to 85, 5 to 85, and −5 to 85 degrees Celsius, the predetermined thresholds can be 0, 5, and −5 degrees Celsius, respectively. In one embodiment, a temperature curve (such as curve 700 of FIG. 7, discussed further below) is further used for the determining of the predetermined thresholds. When monitored temperatures for the components of ADS 110 is above the predetermined temperature thresholds, it is determined that the ADS 110 is safe to power on.

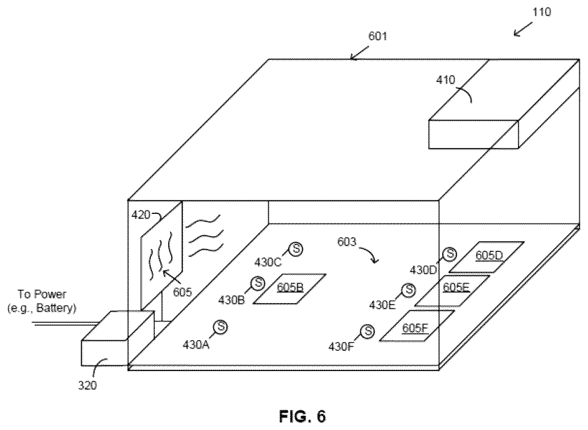

In one embodiment, temperature sensors are disposed near temperature-critical components, such as sensors 430B, 430D, 430E, and 430F of FIG. 6, being disposed within a predetermined distance (e.g., approx. 1 centimeter) to components 605B, 605D, 605E, and 605F, respectively. The monitored temperature for the component can correspond to sensor data for the corresponding temperature sensor. In this case, it can be determined that the ADS 110 is safe to power on when readings of each of temperature sensors 430B, 430D, 430E, and 430F are above predetermined temperature thresholds for the corresponding components.

In another embodiment, the predetermined threshold is a highest of the predetermined thresholds for the different components, and the monitored temperature is an average value from the sensor data for temperature sensors disposed on computing system ADS 110. For example, the predetermined threshold can be the highest of (0, 5, and −5), which equals 5. For the monitored temperature, the monitored temperature can be an average of the temperature readings for temperature sensors 430A-430F which are distributed on computing system ADS 110 as shown in FIG. 6.

In another embodiment, an estimation model (such as a linear model) can be used to estimate the monitored temperature from sensors data of temperature sensors 430A-430F. the linear model can be: y=ax+b, where y denotes the temperature value, x denotes the heat energy applied or the time elapsed, a and b denotes the model parameters. Although six sensors and four components are shown, any number of sensors can be mapped to any number of temperature-critical components. The temperature-critical components can be: CPU, GPU, digital signal processors (DSP), battery, memory devices, storage devices, SoC, temperature sensitive switch chips, or any components that are affected by low temperature conditions.

At block 509, if it is determined safe to power on ADS, a safety system sends a signal to a power system (e.g., power system 410 of FIG. 4) of ADS to power on the ADS computing system.

At block 511, ADS computing system sends a feedback status to safety system, indicating whether the power on sequence is successful.

FIG. 6 is a block diagram illustrating an example of a computing system for ADS 110 according to one embodiment. ADS 110 can include a server chassis 601 housing a server board 603. Server board 603 can include one or more temperature-critical components 605B, and 605D-605F. Temperature sensors 430A-430D can be disposed on server board 603 in a distributed manner. In one embodiment, temperature sensors 430A-430D are distributed in a grid pattern. In another embodiment, temperature sensors 430A-430D are distributed with at least one temperature sensor within a predetermined distance from each of components 605B, 605D-605F.

Server chassis 601 can house power system 410 and thermal management system (e.g., heating module) 420. Thermal management system 420 can include electric heating elements 605 and an active fan 607 to actively radiate the heat from heating elements 605. In another embodiment, thermal management system 420 can be part of the heating ventilation, air conditioning (HVAC) of ADV 101 controlling the temperature and humidity for interior of server chassis 601. In one embodiment, when a temperature reading from temperature sensors 430A-430D is below a predetermined threshold, safety system 320 (a device separate from ADS 110) can activate thermal management system 420 to distribute heat energy to an interior of server chassis 601. In one embodiment, when a temperature reading from temperature sensors 430A-430D is above the predetermined threshold, safety system 320 can de-activate thermal management system 420 and/or send a signal to power system 410 to initiate a power up sequence for server board 605 and various components 605B, and 605D-605F of ADS 110. In one embodiment, the power up sequence powers up sensors systems 115 before powering up ADS 110. Here, ensuring that the various consumer-grade components/server board of ADS 110 is above a temperature threshold decreases a chance of component damage/boot up failure and increases a life expectance of the components of ADS 110.

FIG. 7 is a block diagram illustrating a temperature curve 700 according to one embodiment. Temperature curve 700 can represent a heating profile for components of ADS 110. As shown, temperature curve 700 shows changes in temperature for the components when a relatively constant heating source is applied to the components. Referring to FIG. 7, regions B-C and D-E can correspond to the water vapor in the air that are surrounding the components that undergoes solid-liquid, and liquid-gas phase changes, respectively. Regions B-C (freezing point) and D-E (boiling point) are flat regions corresponding to a flat temperature curve, while regions A-B, C-D, and E-F are sloped regions corresponding to changing temperatures. In one embodiment, the predetermined temperature threshold is set at a sloped region so that the temperature does not reflect a phase change. For example, if a predetermined temperature threshold is set at a flat temperature region, the predetermined temperature threshold can be updated to be 1-3 degrees Celsius above the flat temperature region. In another embodiment, the linear estimation model can be adjusted to take into account the flat regions of the temperature curve. E.g., linear estimation model can include a segment of y=ax+b for each region of the temperature curve.

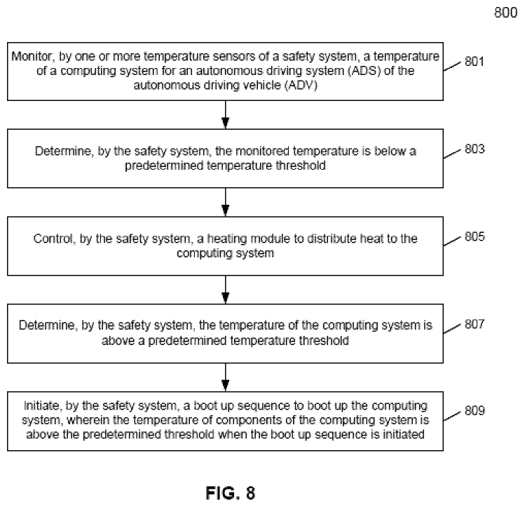

FIG. 8 is a flow diagram illustrating a process according to one embodiment. Process 800 may be performed by processing logic which may include software, hardware, or a combination thereof. For example, process 800 may be performed by safety system 320 of FIG. 4.

At block 801, processing logic monitors, by one or more temperature sensors of the safety system, a temperature of a computing system for an autonomous driving system (ADS) of the autonomous driving vehicle (ADV).

At block 803, processing logic determines the monitored temperature is below a predetermined temperature threshold.

At block 805 processing logic controls a heating module to distribute heat to the computing system.

At block 807, processing logic determines the temperature of the computing system is above a predetermined temperature threshold.

At block 809, processing logic initiates a boot up sequence to boot up the computing system, where the temperature of components of the computing system is above the predetermined threshold when the boot up sequence is initiated.

In one embodiment, determining the temperature of the computing system is above the predetermined temperature threshold further includes for each of the components, estimating a temperature of the component by applying an estimation model to sensor data from the one or more temperature sensors, and determining the estimated temperature of the component is above a predetermined temperature threshold for the component.

In one embodiment, the estimation model is a linear regression model that estimates a temperature of the component using sensor data from one or more temperature sensors.

In one embodiment, determining the temperature of the computing system is above the predetermined temperature threshold further includes determining a temperature curve representative of the components of the computing system, and determining the estimated temperature is at a slope region of the temperature curve.

In one embodiment, the one or more sensors are disposed, in a distributed manner, on a surface of a server board of the computing system.

In one embodiment, one sensor is disposed within a predetermined distance to a central processing unit (CPU) and another sensor is disposed within a predetermined distance to a graphical processing unit (GPU) of the computing system.

In one embodiment, the safety system comprises a vehicle-grade microcontroller (MCU) or a vehicle-grade system-on-a-chip (SOC) a vehicle-grade field programmable gate array (FPGA), wherein the MCU or SOC or FPGA has an operating temperature below the predetermined temperature threshold.

In one embodiment, processing logic further receives a successful boot status indicator from the computing system indicator the computing system has booted successfully.

In one embodiment, the safety system is a device separate from the computing system of the ADS.

Note that some or all of the components as shown and described above may be implemented in software, hardware, or a combination thereof. For example, such components can be implemented as software installed and stored in a persistent storage device, which can be loaded and executed in a memory by a processor (not shown) to carry out the processes or operations described throughout this application. Alternatively, such components can be implemented as executable code programmed or embedded into dedicated hardware such as an integrated circuit (e.g., an application specific IC or ASIC), a digital signal processor (DSP), or a field programmable gate array (FPGA), which can be accessed via a corresponding driver and/or operating system from an application. Furthermore, such components can be implemented as specific hardware logic in a processor or processor core as part of an instruction set accessible by a software component via one or more specific instructions.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. Such a computer program is stored in a non-transitory computer readable medium. A machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments of the present disclosure are not described with reference to any particular programming language. It will be appreciated that a variety of programming languages may be used to implement the teachings of embodiments of the disclosure as described herein.

In the foregoing specification, embodiments of the disclosure have been described with reference to specific exemplary embodiments thereof. It will be evident that various modifications may be made thereto without departing from the broader spirit and scope of the disclosure as set forth in the following claims. The specification and drawings are, accordingly, to be regarded in an illustrative sense rather than a restrictive sense.

1. A computer-implemented method, comprising:
monitoring, by one or more temperature sensors of a safety system, a temperature of a computing system for an autonomous driving system (ADS) of the autonomous driving vehicle (ADV);
determining, by the safety system, the monitored temperature is below a predetermined temperature threshold;
controlling, by the safety system, a heating module to distribute heat to the computing system;
determining, by the safety system, the temperature of the computing system is above a predetermined temperature threshold; and
initiating, by the safety system, a boot up sequence to boot up the computing system, wherein the temperature of components of the computing system is above the predetermined threshold when the boot up sequence is initiated.

2. The method of claim 1, wherein determining the temperature of the computing system is above the predetermined temperature threshold further comprises:
for each of the components, estimating a temperature of the component by applying an estimation model to sensor data from the one or more temperature sensors; and
determining the estimated temperature of the component is above a predetermined temperature threshold for the component.

3. The method of claim 2, wherein the estimation model is a linear regression model that estimates a temperature of the component using sensor data from one or more temperature sensors.

4. The method of claim 2, wherein determining the temperature of the computing system is above the predetermined temperature threshold further comprises:
determining a temperature curve representative of the components of the computing system; and
determining the estimated temperature is at a slope region of the temperature curve.

5. The method of claim 1, wherein the one or more sensors are disposed, in a distributed manner, on a surface of a server board of the computing system.

6. The method of claim 1, wherein one sensor is disposed within a predetermined distance to a central processing unit (CPU) and another sensor is disposed within a predetermined distance to a graphical processing unit (GPU) of the computing system.

7. The method of claim 1, wherein the safety system comprises a vehicle-grade microcontroller (MCU) or a vehicle-grade system-on-a-chip (SOC) a vehicle-grade field programmable gate array (FPGA), wherein the MCU or SOC or FPGA has an operating temperature below the predetermined temperature threshold.

8. The method of claim 1, further comprising: receiving a successful boot status indicator from the computing system indicator the computing system has booted successfully.

9. The method of claim 1, wherein the safety system is a device separate from the computing system of the ADS.

10. A non-transitory machine-readable medium having instructions stored therein, which when executed by a processor, cause the processor to perform operations, the operations comprising:
monitoring, by one or more temperature sensors of a safety system, a temperature of a computing system for an autonomous driving system (ADS) of the autonomous driving vehicle (ADV);
determining, by the safety system, the monitored temperature is below a predetermined temperature threshold;
controlling, by the safety system, a heating module to distribute heat to the computing system;
determining, by the safety system, the temperature of the computing system is above a predetermined temperature threshold; and
initiating, by the safety system, a boot up sequence to boot up the computing system, wherein the temperature of components of the computing system is above the predetermined threshold when the boot up sequence is initiated.

11. The non-transitory machine-readable medium of claim 10, wherein determining the temperature of the computing system is above the predetermined temperature threshold further comprises:
for each of the components, estimating a temperature of the component by applying an estimation model to sensor data from the one or more temperature sensors; and
determining the estimated temperature of the component is above a predetermined temperature threshold for the component.

12. The non-transitory machine-readable medium of claim 11, wherein the estimation model is a linear regression model that estimates a temperature of the component using sensor data from one or more temperature sensors.

13. The non-transitory machine-readable medium of claim 11, wherein determining the temperature of the computing system is above the predetermined temperature threshold further comprises:
determining a temperature curve representative of the components of the computing system; and
determining the estimated temperature is at a slope region of the temperature curve.

14. The non-transitory machine-readable medium of claim 10, wherein the one or more sensors are disposed, in a distributed manner, on a surface of a server board of the computing system.

15. The non-transitory machine-readable medium of claim 10, wherein one sensor is disposed within a predetermined distance to a central processing unit (CPU) and another sensor is disposed within a predetermined distance to a graphical processing unit (GPU) of the computing system.

16. The non-transitory machine-readable medium of claim 10, wherein the safety system comprises a vehicle-grade microcontroller (MCU) or a vehicle-grade system-on-a-chip (SOC) a vehicle-grade field programmable gate array (FPGA), wherein the MCU or SOC or FPGA has an operating temperature below the predetermined temperature threshold.

17. The non-transitory machine-readable medium of claim 10, wherein the operations further comprise: receiving a successful boot status indicator from the computing system indicator the computing system has booted successfully.

18. The method of claim 1, wherein the safety system is a device separate from the computing system of the ADS.

19. A data processing system, comprising:
a processor; and
a memory coupled to the processor to store instructions, which when executed by the processor, cause the processor to perform operations, the operations including
monitoring, by one or more temperature sensors of a safety system, a temperature of a computing system for an autonomous driving system (ADS) of the autonomous driving vehicle (ADV);
determining, by the safety system, the monitored temperature is below a predetermined temperature threshold;
controlling, by the safety system, a heating module to distribute heat to the computing system;
determining, by the safety system, the temperature of the computing system is above a predetermined temperature threshold; and
initiating, by the safety system, a boot up sequence to boot up the computing system, wherein the temperature of components of the computing system is above the predetermined threshold when the boot up sequence is initiated.

20. The system of claim 19, wherein determining the temperature of the computing system is above the predetermined temperature threshold further comprises:
for each of the components, estimating a temperature of the component by applying an estimation model to sensor data from the one or more temperature sensors; and
determining the estimated temperature of the component is above a predetermined temperature threshold for the component.
